(19) United States
(12) Patent Application Publication
(10) Pub. No.: US 2009/0121747 A1
(43) Pub. Date: May 14, 2009

(54) Maintaining Circuit Delay Characteristics During Power Management Mode

(76) Inventors: Sang Hoo Dhong, San Jose, CA (US); Peter Harm Hofstee, Austin, TX (US); Mack Wayne Riley, Austin, TX (US); James Douglas Warnock, Somers, NY (US); Stephen Douglas Weitzel, Round Rock, TX (US)

Correspondence Address: HAMILTON & TERRILE, LLP;IBM Austin, P.O. BOX 203518, AUSTIN, TX, 78720, US

(21) Appl. No.: 11/938,347

(22) Filed: Nov. 12, 2007

(51) Int. Cl. H03K 3/017

(52) U.S. Cl. 327/36; 327/44

(57) ABSTRACT

A system and method for maintaining circuit delay characteristics during power management mode. The method for maintaining circuit delay characteristics during power management mode continually toggles the clock distribution circuits at a frequency sufficiently low that it does not significantly impact chip power dissipation. The clock frequency used to toggle the clock distribution circuits is high enough to minimize the asymmetrical stress on the clock buffer transistors so that both P and N device characteristics equally change over time.

### BACKGROUND OF THE INVENTION

1. Field of the Invention

The present invention relates in general to the field of computers and similar technologies, and in particular to integrated circuits utilized in this field. Still more particularly, the present invention relates to maintaining circuit delay characteristics during power management mode.

2. Description of the Related Art

During an integrated circuit chip power dissipation reduction management mode of operation, it is possible to stop toggling the clock distribution to save chip power dissipation. In this stopped mode, the clock buffer circuits' inputs are not toggling, but set to a deterministic Voltage. This condition can cause some transistors in the buffer circuits to stay in a conducting or “on” state and the remaining transistors to stay in a non-conducting or “off” state. In silicon Metal Oxide Semiconductor (MOS) technology, when a transistor is maintained in the “on” state for a period of time, the electrical characteristics of the transistor can slowly change over that time period so that the device no longer conducts as much current. The changes to the electrical characteristics can result in transistor device degraded performance. When a transistor is maintained in the “off” or non-conducting state, the electrical characteristics of the transistor degrade significantly slower. For purposes of clock distribution, the difference in device performance degradation between “on” and “off” devices occurring when the clock distribution is not toggling, introduces a difference in propagation delay through a clock distribution between a low to high transition and a high to low transition clock signal.

FIGS. 1A-1D, labeled Prior Art, show a block diagram of a simplified clock distribution circuit which includes a clock gating NAND gate, with inputs Clock Signal and Clock Gating Signal, followed by four inverting clock buffers, and a clock signal receiving circuit with a clock signal input and a gating signal input. When the clock signal is gated “off”, certain transistors within the clock buffer circuits are stressed and change electrical characteristics. These stressed devices delay propagation of the logic high to low clock signal, causing the clock signal pulse width to increase or decrease over time. This pulse width increase is undesirable and could cause the chip to no longer function. More specifically FIG. 1A generally shows the clock distribution block circuit. FIG. 1B shows the clock distribution circuit where a rising clock signal edge propagates through the clock buffer stages such that the transistors 110, 112, 114, 126 are conducting. FIG. 1C shows the clock distribution circuit where a falling clock signal edge propagates through the clock buffer stages such that the transistors 120, 122, 124, 126 are conducting. FIG. 1D shows the clock distribution circuit when the clock signal is gated off such that certain transistors (e.g., transistors 120, 122, 124, 126) within the clock buffer circuit are stressed and thus change electrical characteristics over time.

### SUMMARY OF THE INVENTION

In accordance with the present invention, a system and method for maintaining circuit delay characteristics during power management mode is shown. More specifically, the method for maintaining circuit delay characteristics during power management mode continually toggles the clock distribution circuits at a frequency sufficiently low that it does not significantly impact chip power dissipation. The clock frequency used to toggle the clock distribution circuits is high enough to minimize any asymmetrical stress on the clock buffer transistors so that both P and N device characteristics equally change over time. Asymmetrical stress can occur when a clock signal is set to a static logic level because one group of P and N devices are stressed while another group of P and N devices are not stressed.

In certain embodiments of the clock distribution circuits, a gated NAND gate is replaced with a multiplexer (i.e., a selector) circuit. When a lower clock distribution power dissipation is required, the low frequency clock signal is selected for the clock distribution. The lower clock frequency signal continues to toggle both the P and N devices so that each device is stressed about the same amount of time when the low frequency clock signal is about 50% duty cycle. If it is determined the P and N devices change electrical characteristics at different rates over time, the low frequency clock signal duty cycle is adjusted accordingly to compensate for the different rate changes.

More specifically, in one embodiment, the invention relates to an apparatus for maintaining circuit characteristics which includes a selector circuit, a buffer circuit coupled to the selector circuit, and a receive circuit coupled to the buffer circuit. The selector circuit receives a clock signal, a power saving clock signal and a clock gating signal. The clock gating signal causes the selector circuit to pass the power saving clock signal to the buffer circuit when the apparatus is operating in a power saving mode of operation. The power saving clock signal continually toggles the buffer circuit at a frequency sufficiently low so at to not impact chip power dissipation while being high enough to minimize asymmetrical stress within the buffer circuit.

In another embodiment, the invention relates to a method for maintaining circuit characteristics which includes generating a clock signal, a power saving clock signal and a clock gating signal, selecting one of the clock signal and the power saving clock signal with the clock gating signal to provide a selected clock signal, and providing the selected clock signal to a buffer circuit, the clock gating signal being provided to the buffer circuit to operate the buffer circuit in a power saving mode of operation, the power saving clock signal continually toggling the buffer circuit at a frequency sufficiently low so at to not impact chip power dissipation while being high enough to minimize asymmetrical stress within the buffer circuit.

In another embodiment, the invention relates to a data processing system comprising a clock circuit. The clock circuit includes a selector circuit which receives a clock signal, a power saving clock signal and a clock gating signal, a buffer circuit coupled to the selector circuit, the clock gating signal causing the selector circuit to pass the power saving clock signal to the buffer circuit when the apparatus is operating in a power saving mode of operation, the power saving clock signal continually toggling the buffer circuit at a frequency sufficiently low so at to not impact chip power dissipation while being high enough to minimize asymmetrical stress within the buffer circuit, and a receive circuit coupled to the buffer circuit.

The above, as well as additional purposes, features, and advantages of the present invention will become apparent in the following detailed written description.

### BRIEF DESCRIPTION OF THE DRAWINGS

The novel features believed characteristic of the invention are set forth in the appended claims. The invention itself, however, as well as a preferred mode of use, further purposes and advantages thereof, will best be understood by reference to the following detailed description of an illustrative embodiment when read in conjunction with the accompanying drawings, where:

FIGS. 1A-1D, labeled Prior Art, show a simplified clock distribution block diagram.

FIG. 2 shows a block diagram of a clock distribution circuit in accordance with the present invention.

FIG. 3 shows a block diagram of a clock distribution circuit in accordance with the present invention.

FIG. 4 shows a block diagram of a representative data processing system suitable for practicing the principles of the present invention.

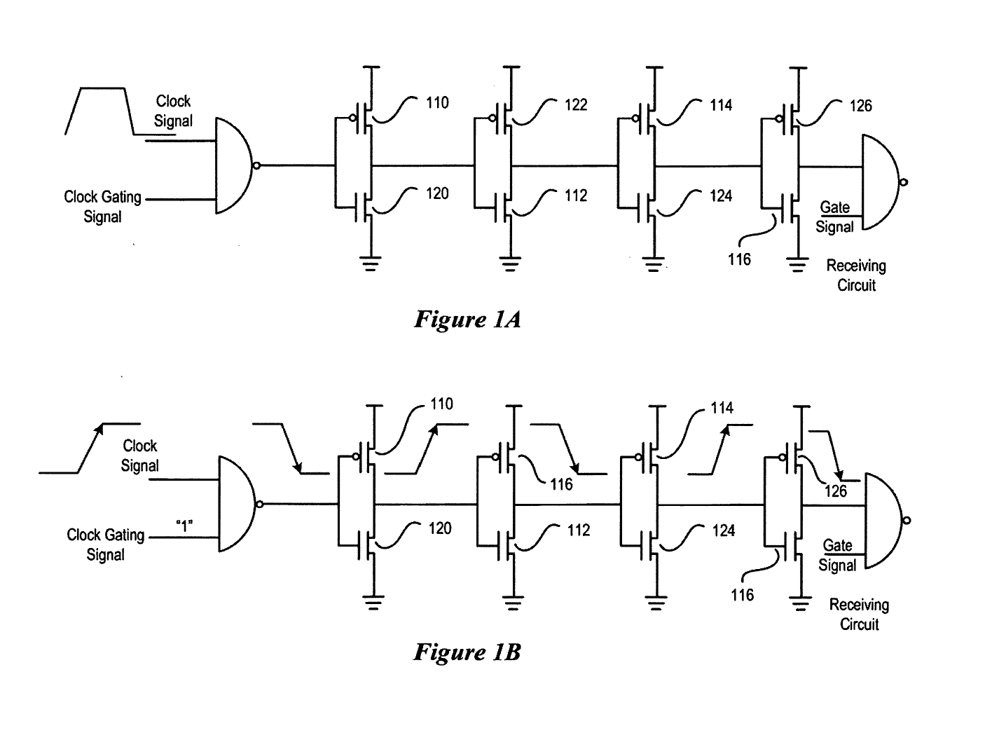

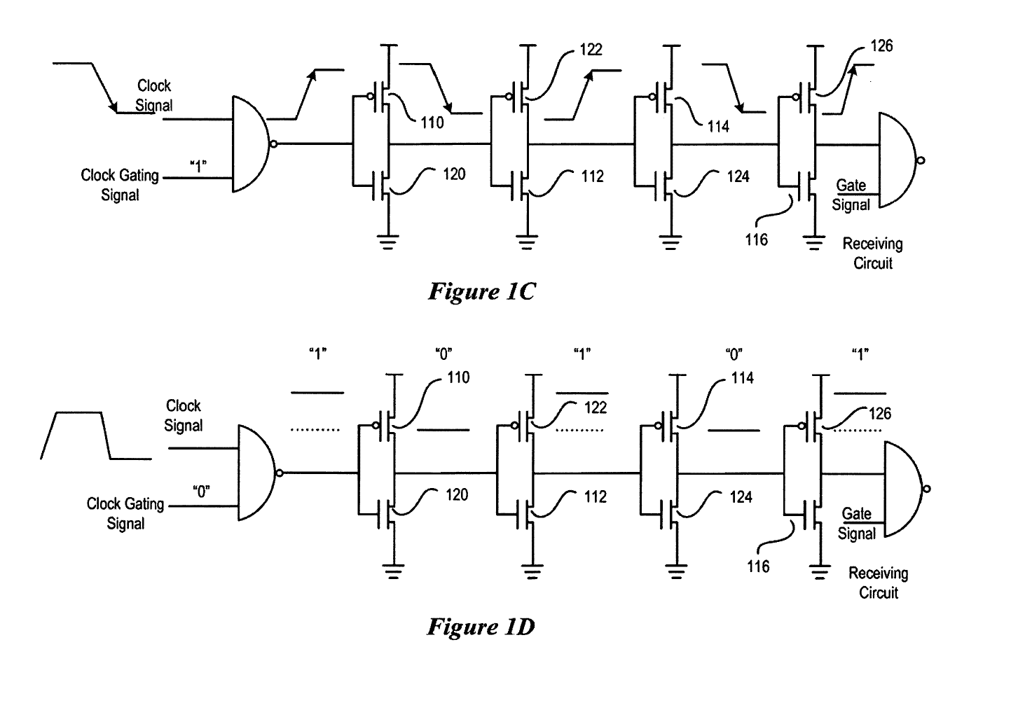

### DETAILED DESCRIPTION

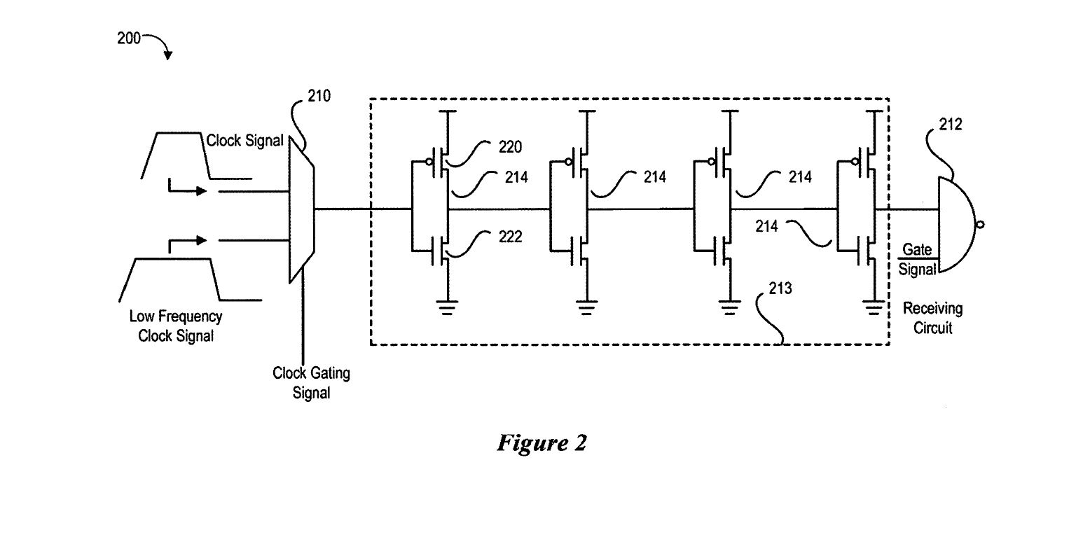

Referring to FIG. 2, a clock distribution circuit 200 which maintains circuit delay characteristics during power management mode is shown. More specifically, the clock distribution circuit 200 includes a multiplexer 210 (i.e., a selector) circuit 210 as well as a receiving circuit 212. Coupled between the multiplexer 210 and the receiving circuit 212 is a buffer circuit 213. The buffer circuit 213 comprises a plurality of buffers (e.g., inverters) 214. Each of the buffers 214 includes a p-type transistor 220 and an n-type transistor 222. It will be appreciated that while the example clock distribution circuit is shown with four buffers 214, any number of buffers could, and likely would, be included within the buffer circuit 213.

The multiplexer 210 receives a clock signal, a low frequency clock signal (e.g., a clock signal that is a small percentage (e.g., less than 5%) of the clock signal) as well as a clock gating signal. The multiplexer 210 provides a clock signal to the first of the series of buffers 214. The receiving circuit 212 receives the output of the buffers as well as a clock gate signal.

In the clock distribution circuit 200, a gated NAND gate is replaced with the multiplexer (i.e., a selector) circuit 210. The selector circuit, which is controlled by the clock gating signal generated by power management function (not shown), allows a low frequency clock signal (i.e., a power management clock signal) to be applied to the buffer circuit 213. When a lower power dissipation is desired, the low frequency clock signal is selected via the clock gating signal for the clock distribution. The lower clock frequency signal continues to toggle both the P and N devices so that each device is stressed about the same amount of time. The low frequency clock signal is initially generated with about a 50% duty cycle. If it is determined that the P and N devices are changing electrical characteristics at different rates over time, the low frequency clock signal duty cycle can be adjusted accordingly to compensate for the different rate changes.

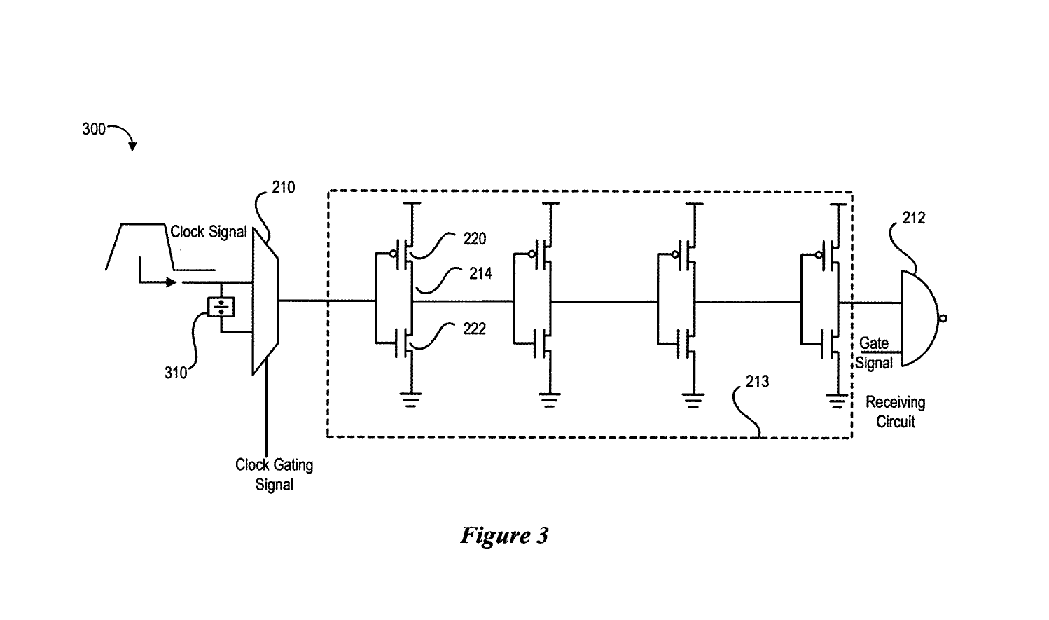

Referring to FIG. 3, a clock distribution circuit 300 which maintains circuit delay characteristics during power management mode is shown. More specifically, the clock distribution circuit 300 includes a multiplexer 210 (i.e., a selector) circuit 210 as well as a receiving circuit 212. Coupled between the multiplexer 210 and the receiving circuit 212 is a buffer circuit 213. The buffer circuit 213 comprises a plurality of buffers (e.g., inverters) 214. Each of the buffers 214 includes a p-type transistor 220 and an n-type transistor 222.

The clock distribution circuit 300 also includes a divider 310. The divider receives the clock signal and divides the clock signal by a predetermined amount to provide the low frequency clock signal. In one embodiment, the divider 310 divides the clock signal by 64 to provide the low frequency clock signal, thus providing a low frequency clock signal with a frequency that is less than two percent of the frequency of the clock signal.

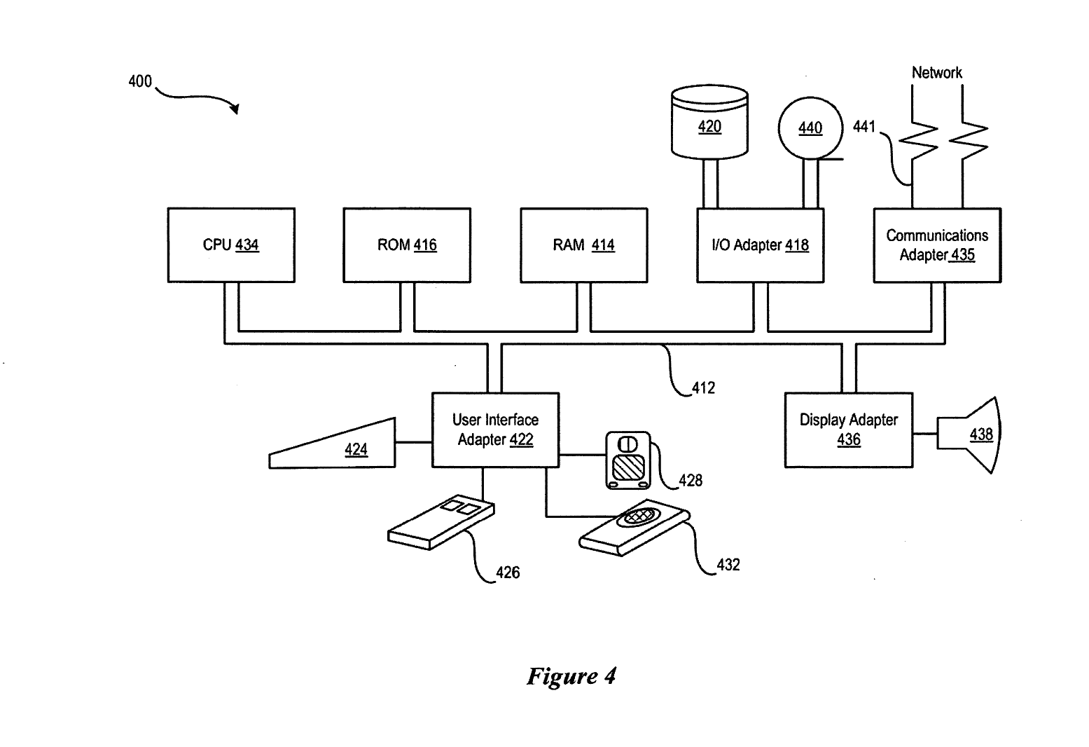

FIG. 4 is a high level functional block diagram of a representative data processing system 400 suitable for practicing the principles of the present invention. Data processing system 400 includes a central processing system (CPU) 410 operating in conjunction with a system bus 412. System bus 412 operates in accordance with a standard bus protocol, such as the ISA protocol, compatible with CPU 434. CPU 434 operates in conjunction with electronically erasable programmable read-only memory (EEPROM) 416 and random access memory (RAM) 414. Among other things, EEPROM 416 supports storage of the Basic Input Output System (BIOS) data and recovery code. RAM 414 includes DRAM (Dynamic Random Access Memory) system memory and SRAM (Static Random Access Memory) external cache. I/O Adapter 418 allows for an interconnection between the devices on system bus 412 and external peripherals, such as mass storage devices (e.g., a hard drive, floppy drive or CD/ROM drive), or a printer 440. A peripheral device 420 is, for example, coupled to a peripheral control interface (PCI) bus, and I/O adapter 418 therefore may be a PCI bus bridge. User interface adapter 422 couples various user input devices, such as a keyboard 424 or mouse 426 to the processing devices on bus 412. Display 438 which may be, for example, cathode ray tubes (CRT), liquid crystal display (LCD) or similar conventional display units. Display adapter 436 may include, among other things, a conventional display controller and frame buffer memory. Data processing system 400 may be selectively coupled to a computer or telecommunications network 441 through communications adapter 434. Communications adapter 434 may include, for example, a modem for connection to a telecom network and/or hardware and software for connecting to a computer network such as a local area network (LAN) or a wide area network (WAN). CPU 434 and other components of data processing system 400 may contain DLL circuitry for local generation of clocks wherein the DLL circuitry employs a phase detector according to embodiments of the present invention to conserve power and to reduce phase jitter. A phase detector in accordance with the present invention may be found within a variety of elements within the data processing system.

Although the present invention and its advantages have been described in detail, it should be understood that various changes, substitutions and alterations can be made herein without departing from the spirit and scope of the invention as defined by the appended claims.

For example, in certain embodiments, it is possible to purposely distort the lower frequency clock signal duty cycle so that during the power management mode certain P and N devices are pre-stressed to counteract any device degradation occurring in the buffering tree during functional mode. In certain timing circuits, a non 50% duty cycle functional clock signal may be generated as such a clock signal can provide a higher processor operating frequency than a 50% duty cycle signal due to receiving circuit design characteristics. Toggling the clock distribution buffers with a non 50% duty cycle clock signal, over time, can potentially affect the device characteristics of the clock circuit thus causing a change the clock signal duty cycle. This effect may be nulled by distorting the lower frequency clock signal in such a way as to overly stress, during power management operations, the relatively unstressed devices and achieve, overall, a balanced stressing of all devices.

As will be appreciated by one skilled in the art, the present invention may be embodied as a method, system, or computer program product. Accordingly, the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present invention may take the form of a computer program product on a computer-usable storage medium having computer-usable program code embodied in the medium.

As will be appreciated by one skilled in the art, while the present invention, and circuits within the present invention are described using certain combinations of logic, other logic combinations are also within the scope of the invention. For example, it will be appreciated other logic combinations to provide a delay circuit and a stretching circuit are known. Also, it will be appreciated that changing the polarity of the logic gates, e.g., from AND to NAND, are also within the scope of the invention.

The block diagrams in the Figures illustrate the architecture, functionality, and operation of possible implementations of systems and methods according to various embodiments of the present invention. It will also be noted that each block of the block diagrams, and combinations of blocks in the block diagrams, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the present invention, a transistor may be conceptualized as having a control terminal which controls the flow of current between a first current handling terminal and a second current handling terminal. An appropriate condition on the control terminal causes a current to flow from/to the first current handling terminal and to/from the second current handling terminal. In a bipolar NPN transistor, the first current handling terminal is the collector, the control terminal is the base, and the second current handling terminal is the emitter. A sufficient current into the base causes a collector-to-emitter current to flow. In a bipolar PNP transistor, the first current handling terminal is the emitter, the control terminal is the base, and the second current handling terminal is the collector. A current exiting the base causes an emitter-to-collector current to flow.

A MOS transistor may likewise be conceptualized as having a control terminal which controls the flow of current between a first current handling terminal and a second current handling terminal. Although MOS transistors are frequently discussed as having a drain, a gate, and a source, in most such devices the drain is interchangeable with the source. This is because the layout and semiconductor processing of the transistor is symmetrical (which is typically not the case for bipolar transistors). For an N-channel MOS transistor (also referred to as an N type transistor or an N device), the current handling terminal normally residing at the higher voltage is customarily called the drain. The current handling terminal normally residing at the lower voltage is customarily called the source. A sufficient voltage on the gate causes a current to therefore flow from the drain to the source. The gate to source voltage referred to in an N channel MOS device equations merely refers to whichever diffusion (drain or source) has the lower voltage at any given time. For example, the “source” of an N channel device of a bi-directional CMOS transfer gate depends on which side of the transfer gate is at a lower voltage. To reflect the symmetry of most N channel MOS transistors, the control terminal is the gate, the first current handling terminal may be termed the “drain/source”, and the second current handling terminal may be termed the “source/drain”. Such a description is equally valid for a P channel MOS transistor (also referred to as a P type transistor or a P device), since the polarity between drain and source voltages, and the direction of current flow between drain and source, is not implied by such terminology. Alternatively, one current-handling terminal may be arbitrarily deemed the “drain” and the other deemed the “source”, with an implicit understanding that the two are not distinct, but interchangeable

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described the invention of the present application in detail and by reference to preferred embodiments thereof, it will be apparent that modifications and variations are possible without departing from the scope of the invention defined in the appended claims.

What is claimed is:

1. An apparatus for maintaining circuit characteristics comprising
a selector circuit, the selector circuit receiving a clock signal, a power saving clock signal and a clock gating signal;
a buffer circuit coupled to the selector circuit, the clock gating signal causing the selector circuit to pass the power saving clock signal to the buffer circuit when the apparatus is operating in a power saving mode of operation, the power saving clock signal continually toggling the buffer circuit at a frequency sufficiently low so at to not impact chip power dissipation while being high enough to minimize asymmetrical stress within the buffer circuit; and,
a receive circuit coupled to the buffer circuit.

2. The apparatus of claim 1 wherein
the buffer circuit comprises a plurality of buffers, each of the plurality of buffers comprising a P-type device and an N-type device; and,
the frequency of the power saving clock signal is high enough to minimize asymmetrical stress on the buffer circuit devices so that electrical characteristics of the P-type device and the N-type device equally change over time.

3. The apparatus of claim 1 further comprising:
a divider receiving the clock signal, the divider generating the power saving clock signal.

4. The apparatus of claim 1 wherein:
a frequency of the power saving clock signal is a small percentage of a frequency of the clock signal.

5. The apparatus of claim 1 wherein:
the clock signal comprises a non-50% duty cycle; and,
the power saving clock signal is distorted to null asymmetrical stress caused by the non-50% duty cycle.

6. A method for maintaining circuit characteristics comprising
generating a clock signal, a power saving clock signal and a clock gating signal
selecting one of the clock signal and the power saving clock signal with the clock gating signal to provide a selected clock signal;
providing the selected clock signal to a buffer circuit, the clock gating signal being provided to the buffer circuit to operate the buffer circuit in a power saving mode of operation, the power saving clock signal continually toggling the buffer circuit at a frequency sufficiently low so at to not impact chip power dissipation while being high enough to minimize asymmetrical stress within the buffer circuit.

7. The method of claim 6 wherein
the buffer circuit comprises a plurality of buffers, each of the plurality of buffers comprising a P-type device and an N-type device; and,
the frequency of the power saving clock signal is high enough to minimize asymmetrical stress on the buffer circuit devices so that electrical characteristics of the P-type device and the N-type device equally change over time.

8. The method of claim 6 further comprising:
generating the power saving clock signal by dividing the clock signal.

9. The method of claim 6 wherein:
a frequency of the power saving clock signal is a small percentage of a frequency of the clock signal.

10. The method of claim 1 wherein:
the clock signal comprises a non-50% duty cycle; and,
the power saving clock signal is distorted to null asymmetrical stress caused by the non-50% duty cycle.

11. A data processing system comprising:
a clock circuit, the clock circuit comprising
a selector circuit, the selector circuit receiving a clock signal, a power saving clock signal and a clock gating signal;
a buffer circuit coupled to the selector circuit, the clock gating signal causing the selector circuit to pass the power saving clock signal to the buffer circuit when the apparatus is operating in a power saving mode of operation, the power saving clock signal continually toggling the buffer circuit at a frequency sufficiently low so at to not impact chip power dissipation while being high enough to minimize asymmetrical stress within the buffer circuit; and,
a receive circuit coupled to the butter circuit.

12. The data processing system of claim 11 wherein
the buffer circuit comprises a plurality of buffers, each of the plurality of buffers comprising a P-type device and an N-type device; and,
the frequency of the power saving clock signal is high enough to minimize asymmetrical stress on the buffer circuit devices so that electrical characteristics of the P-type device and the N-type device equally change over time.

13. The data processing system of claim 11 further comprising:
a divider receiving the clock signal, the divider generating the power saving clock signal.

14. The data processing system of claim 11 wherein:
a frequency of the power saving clock signal is a small percentage of a frequency of the clock signal.

15. The data processing system of claim 11 wherein:
the clock signal comprises a non-50% duty cycle; and,
the power saving clock signal is distorted to null asymmetrical stress caused by the non-50% duty cycle.
